(19) United States
(12) Patent Application Publication
(10) Pub. No.: US 2015/0001713 A1
(43) Pub. Date: Jan. 1, 2015

(54) MULTIPLE LEVEL REDISTRIBUTION LAYER FOR MULTIPLE CHIP INTEGRATION

(71) Applicants: Edmund Goetz, Dachau (DE); Bernd Memmler, Riemerling (DE); Wolfgang Molzer, Ottobrunn (DE); Reinhard Mahnkopf, Oberhaching (DE)

(72) Inventors: Edmund Goetz, Dachau (DE); Bernd Memmler, Riemerling (DE); Wolfgang Molzer, Ottobrunn (DE); Reinhard Mahnkopf, Oberhaching (DE)

(21) Appl. No.: 13/931,899

(22) Filed: Jun. 29, 2013

(51) Int. Cl. H01L 23/00; H01L 25/065; H01L 23/498

(52) U.S. Cl. CPC H01L 24/81; H01L 23/49816; H01L 25/0655
USPC 257/738; 438/107; 257/734

(57) ABSTRACT

A package with multiple chips and a shared redistribution layer is described. In one example, a first and a second die are formed where the first and the second die each have a different height. The dies are placed on a substrate. The first, the second, or both dies are ground so that the first and the second die are about the same height. Layers, such as redistribution layers are formed over both the first and the second die at the same time using a single process, and the first and the second die and the formed layers are packaged.

### FIELD

The present disclosure relates to the field of multiple chip packaging and, in particular, to placing chips of different types into a single package.

### BACKGROUND

Semiconductor and micromechanical dies or chips are frequently packaged for protection against an external environment. The package provides physical protection, stability, external connections, and in some cases, cooling to the die inside the packages. Typically the die is attached to a substrate and then a cover that attaches to the substrate is placed over the die. While there is a trend to add more functions to each die, there is also a trend to put more than one chip in a single package. Since a package is typically much larger than the die that it contains, additional dies can be added without significantly increasing the size of the package. Current packaging technologies include stacking dies on top of each other and placing the dies side-by-side on a single package substrate. Consolidating more functions into a single die and placing more dies into a single package are ways to reduce the size of the electronics and micromechanics in a device.

Some desktop and notebook systems already combine a central processing unit and a graphics processor in a single package. In other cases, a memory die is combined in a package with a processor. For portable devices, more dies may be added to a package to form what is referred to as a complete SiP (System in a Package).

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1A is a cross sectional side view diagram of a portion of a multiple chip package according to an embodiment.

FIG. 1B is a top view diagram of the package of FIG. 1A.

FIG. 2A is a cross sectional side view diagram of a multiple chip wire bonded package according to an embodiment.

FIG. 2B is a cross sectional side view diagram of a multiple chip flip chip package according to an embodiment.

FIG. 3A is a cross sectional side view diagram of a multiple chip embedded wafer level ball grid array package according to an embodiment.

FIG. 3B is a cross sectional side view diagram of a stacked multiple chip embedded wafer level ball grid array package according to an embodiment.

FIGS. 4A-4I are cross sectional side view diagrams of forming a multiple chip package according to an embodiment.

FIG. 5 is a block diagram of a computing device incorporating a multiple die package according to an embodiment.

### DETAILED DESCRIPTION

While similar types of chips made using similar technologies, such as central and graphics processors, may easily be combined in a single package, it is more difficult to combine different types of chips. This is in part due to the different sizes, different connection technologies, and different materials that may be used in different types of chips.

In order to place more of a complete system in a single package, different types of chips may be packaged together. Multiple chip packaging may be extended with a multiple level RDL (Redistribution Layer) for power and ground routing, for I/O (Input/Output) connections, for interconnects between the different chips, and for passive components like inductors. The multiple level RDL may be implemented in a wide variety of different types of packages including WLB (Wafer Level Ball Grid Array) and eWLB (Embedded WLB) packages.

In the examples described herein, different chips useful for a complete portable device are processed each in its own process technology in the FEOL (Front End Of the Line) up to a last metal layer. This last metal layer forms the interface to the multi-level RDL. The different chips are then placed together on a common substrate. In the BEOL (Back End Of the Line) stage, these chips are built together in common process steps. The process steps may include several metal levels and via levels for the redistribution layers.

Several chips may be processed together from a variety of different types of technologies. These can include different CMOS (Complementary Metal Oxide Semiconductor) technologies, such as 22 nm, 65 nm etc., BiCMOS (Bipolar and CMOS), bipolar, and GaAs or other hetero-junction technologies. The chips may be digital circuitry, micromechanical, analog circuitry, optical system, radio systems, or a combination of these or other types of chips. Due to the different technologies, the chips are processed separately in their own FEOL up to the last metal layer which forms a standardized interface to the next common or shared RDL layers.

After the chips are joined together through a common substrate, carrier or other device, the RDL and via layers are processed in a common BEOL. A filler layer may then be introduced to embed the different chips and to ensure stability. The filler layer may also be used to isolate aggressive (digital) and sensitive RF (Radio Frequency) circuits from each other. An appropriate material may be selected for its shielding properties, depending on the particular implementation.

While the chips may come from different processes and be built to different dimensional standards, the chips can all be conformed to an equal height by grinding the backside layers. The chips may be ground to different heights in a single grinding process, where the amount of grinding for each chip depends on the height of the different metal stacks and the wafer thickness. A common or equal height from the front side layers allows a common RDL to be more easily formed over the back side of the chips. In one example, alternating metal and dielectric layers on the top side of the die are ground down.

A System in a Package (SiP) is a combination of multiple active electronic components of different functionality assembled in a single unit. A SiP provides multiple functions associated with a system or sub-system. A SiP may also contain passive components, MEMS (Micro-Electro-Mechanical Systems), optical components, radio components, and other packages and devices.

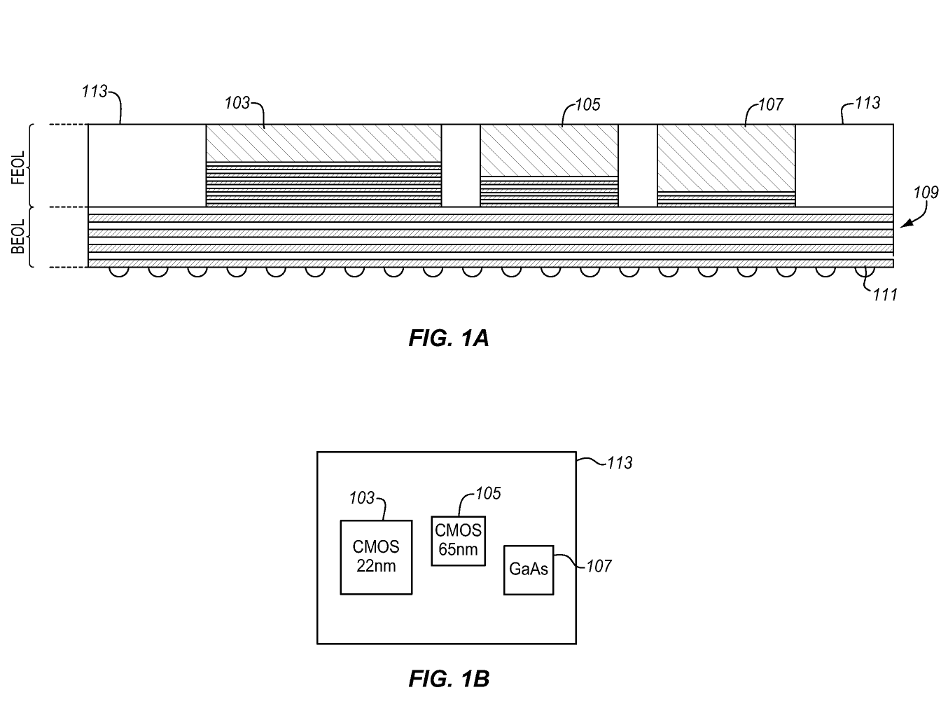

FIG. 1A is cross sectional side view diagram of a portion of a package for a SiP package. The package has a variety of different kinds of dies. In this example there is a first CMOS (Complementary Metal-Oxide Semiconductor) die 103 made using a 22 nm process, a second CMOS die 105 made using a 65 nm process and a third die which is a GaAs die 107. These are all placed on a BEOL substrate 109 so that the metal layers of the FEOL connect to the substrate 109. The substrate is a multiple layer RDL (Redistribution Layer) in the BEOL. A ball grid array 111 is attached to the opposite side of the RDL to connect each of the dies to a PCB (Printed Circuit Board) or to some other device or structure. Filler 113 has been applied to the substrate in between each of the dies for isolation and stability.

FIG. 1B is a top view diagram of the SiP package of FIG. 1A showing each of the three dies 103, 105, 107 and the filler 113. The SiP allows different dies to be attached to a single substrate so that different functions can be accomplished in a small space. Often, these different dies will have different dimensions due to being formed in different processes. In order to allow additional layers, whether back side or front side layers, to be applied to each die at the same time and in a single process, the dies must be the same height. In other words, the dies should have a vertical extent, as shown in FIG. 1A, that is about the same as the others.

The dies shown in the side view diagram of FIG. 1A each have different heights but the metal stacks have been ground to about the same height. An RDL to interconnect the dies is applied directly to the routing layers of the dies. The height of each die can be modified by grinding the metal stack of the die. In alternative embodiments, if the dies are built on a thick substrate, then the substrate can be thinned. On the other hand, if the dies have top isolation or filler layers, then these layers can be ground to a consistent height.

In practice, a package such as that of FIGS. 1A and 1B would be constructed by first placing the three dies on a temporary carrier (not shown), optionally covering the dies in a molding compound and then grinding the metal stacks of each die to achieve the same height. The BEOL layers are then formed on the side opposite the temporary carrier and the temporary carrier is removed.

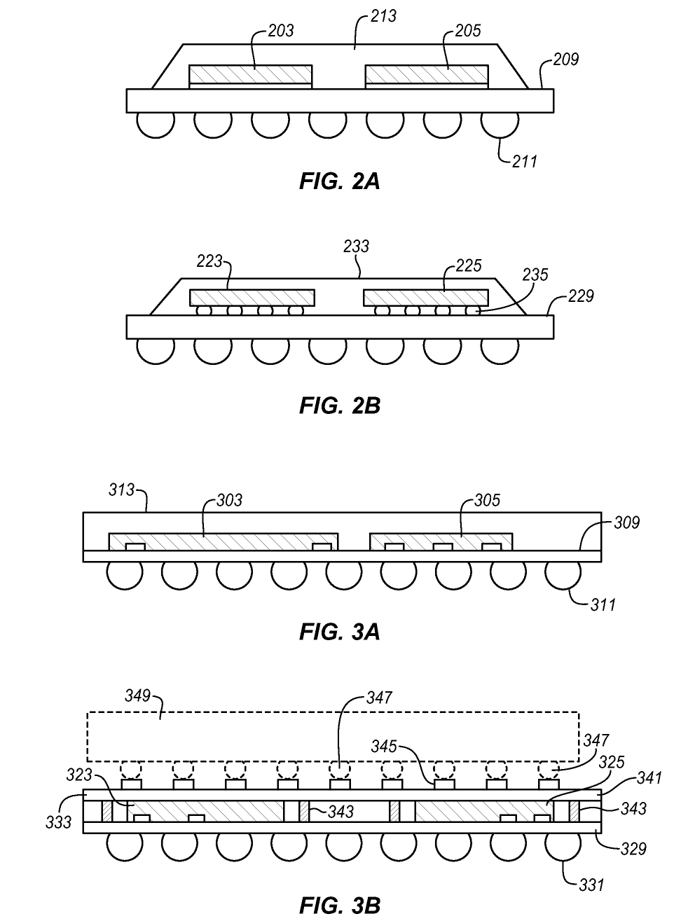

FIG. 2A shows another cross-sectional side view example of a system in a package with two dies 203, 205 attached to a package substrate 209 and covered with a filler layer 213. The dies are placed side by side on the substrate and isolated from each other by the filler. A ball grid array 211 is attached to the bottom of the substrate for connection to, for example, a PCB. The dies may connect directly to the substrate through an array of connection pads or by wire bonds (not shown) extending from the top of each die to connection pads on the substrate or both.

FIG. 2B shows an example of a flip chip SIP. In this cross-sectional side view two dies 223, 225 are directly soldered to a package substrate 229 through electrical connection pads using solder balls. As in the example of FIG. 2A, a filler 233 is applied over the top of and between the dies. The dies are placed in a flip chip figuration and are attached by a solder ball array 235. In the example of FIG. 2A and 2B, as in the example of 1A, the different dies may be of different types and with different dimensions.

FIG. 3A shows yet another example of a multiple die package. FIG. 3A is a cross sectional side view of a first 303 and second 305 die attached to a package substrate 309.

The package of FIG. 3A is a eWLB (embedded Wafer Level Ball grid array). The substrate 309 includes an RDL that connects to a ball grid array 311. The substrate 309 and the dies 303, 305 are covered in a molding compound 313.

FIG. 3B shows how a similar eWLB package with multiple dies can be modified to accommodate another package for a package stack. The first package has a die of one type 323 and a second die of another type 325. These dies are attached to a substrate 329 with an RDL. Another RDL 341 is formed over the top of the two dies and the RDL are electrically connected to each other by vias and wire connections 343. The lower RDL connects through a ball grid array 331 to, for example, a PCB. The upper RDL provides lands 345 to connect with a ball grid array 347 of a second package 349. This allows the packages to be stacked. The stacked configuration may be better for some applications than the side-by-side configuration.

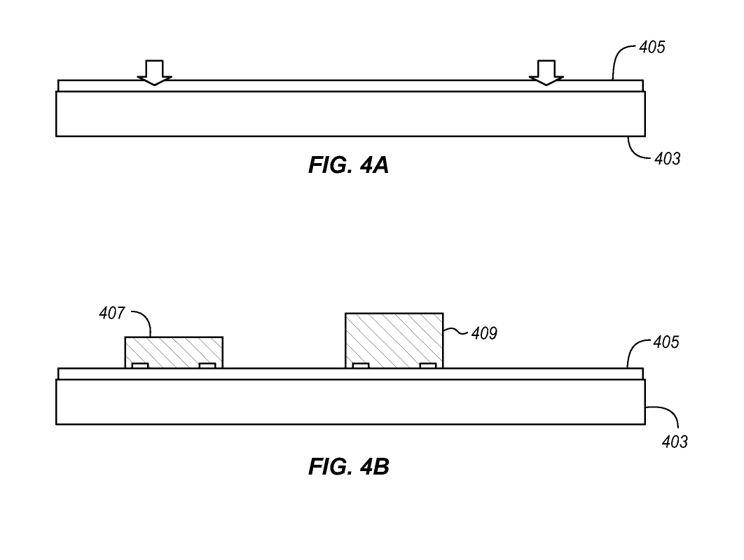

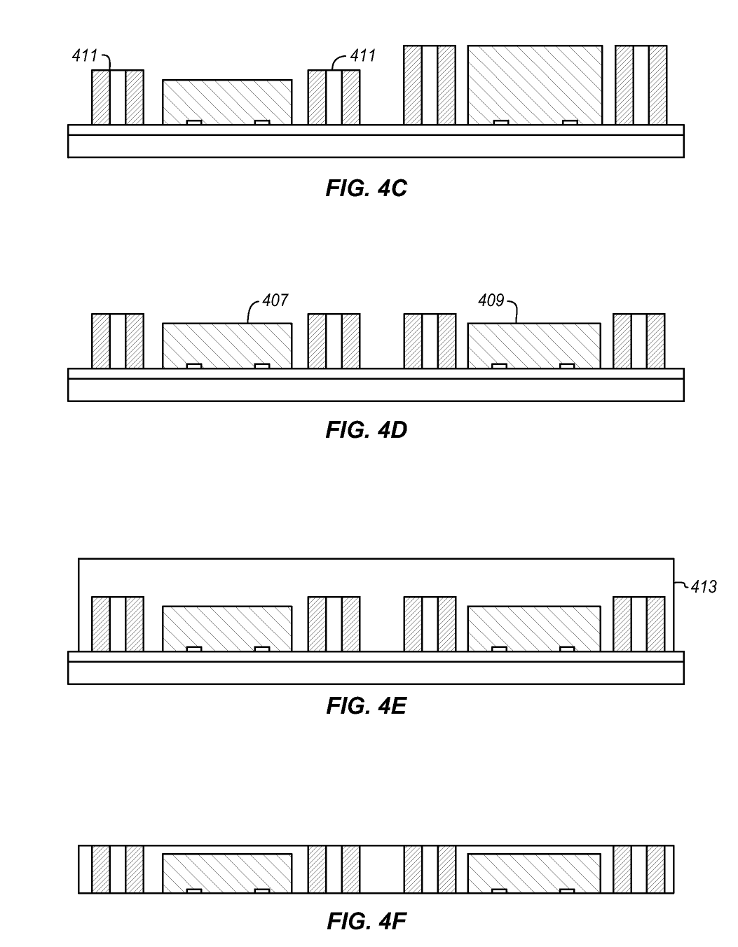

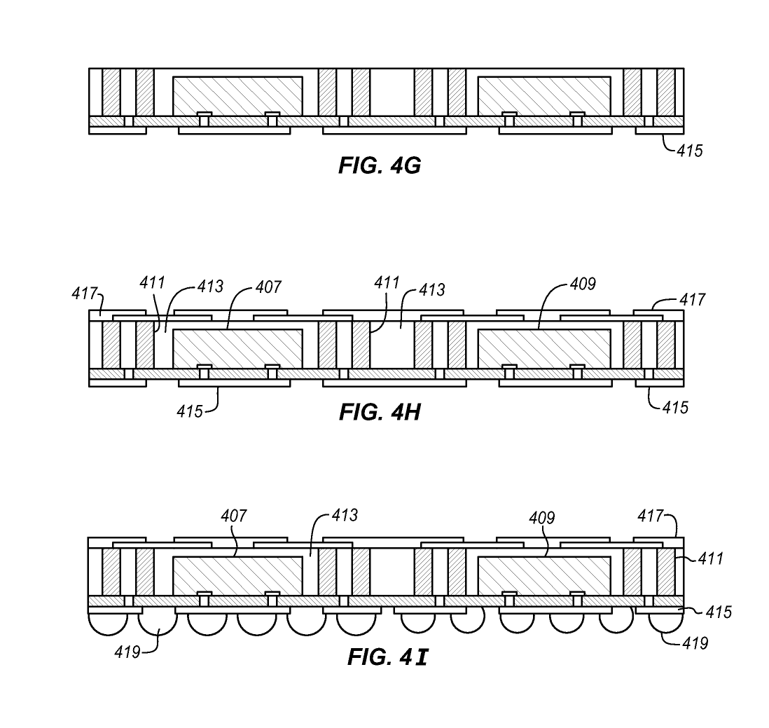

In each of the package examples described above, the dies that are placed on the substrate may be of different types and of different dimensions. These dies may all be placed onto a package substrate and used in a common package after the sizes of the dies are conformed to a common set of dimensions. FIGS. 4A to 4I show a sequence of operations that allow dies of different sizes to be placed into a single package.

FIG. 4A is cross sectional diagram of a carrier 403 to which a foil layer 405 has been laminated. The carrier provides a temporary holder for constructing a package and the foil provides a metal conducting layer which can be used for the later building up of a ball grid array. FIG. 4A represents one possible starting configuration for creating a multiple die package having dies that initially are different dimensions. The foil is laminated to the carrier using high pressure and, in some cases, an adhesive.

In FIG. 4B, a pick and place tool or some other similar device has been used to place a first die of one type 407 and a second die 409 of another type onto the laminated foil of the substrate. In the illustrated example, the second die is taller than the first die due to the difference in its fabrication process. The die may be of a similar type but made in a different process as in the example of the two CMOS dies 103, 105 of FIG. 1A or the die may be of a completely different type as in the example of the GaAs die 107 of FIG. 1A. The dies are placed and attached to the foil layer 405 using, for example, an adhesive.

FIG. 4C shows the addition of via bars 411 between the dies. In the example of this eWLB package, the via bars will connect a lower RDL to an upper RDL on the opposite side of the dies as the package is constructed. In FIG. 4D the two dies 407, 409 are ground in the vertical or Z-direction to make the dies have the same vertical extent. With the dies at the same height, connections between, over, and around the dies are made easier.

In FIG. 4E a molding compound 413 has been applied over the top of the dies to hold the vias and the dies securely in place for further operations. In FIG. 4F the backside layers including the carrier have been removed by grinding, by a solvent, or any of a variety of other ways.

In FIG. 4G the removal of the backside carrier allows a backside redistribution layer 415 to be formed on the back side of the package. This redistribution layer may have one or many metal layers separated by dielectric layers and connected by vertical vias. The metal layers connect contacts on the dies to external devices. In FIG. 4H, a top side redistribution layer 417 is applied over the molding compound 413. The top side redistribution layer may be coupled to the bottom side redistribution layer 415 using the vias 411. There may also be connections through the dies, through wire bonds, or through other direct contact connections.

In FIG. 4I, a ball grid array 419 is applied to one or both sides of the package. The solder ball contacts of the ball grid array connect the redistribution layer 415 to a PCB or other device. As can be seen in the example of FIG. 4I, the two dies are contained within the vias and redistribution layers of the eWLB package. Because the two dies have similar vertical dimensions, the redistribution layers can be formed in a single process that accommodates and connects with both types of dies.

While the package of FIG. 4I is shown having a bottom and a top redistribution layer, only one redistribution layer may be necessary, depending on the particular implementation. Either the bottom side 415 or the top side 417 layer may be used without the other. If two redistribution layers are used, the top side layer may be used for connection to a second package as in the example of FIG. 3B. Alternatively, one layer may be used for power while the other layer is used for data signaling. Alternatively, one layer, such as the bottom layer or back side layer, may be used for connection to the PCB while the other layer, the top side layer 417, may be used to connect the two dies to each other.

Any of the packages described above may use different or additional covers or other protection than that shown. For example, a metal shield, a plastic or ceramic hermetically sealed protective cover, or molding compound may be used alone or in combination with the other materials, depending on the particular implementation.

The small and compact multi-chip packages described herein can be used to build a SiP (System in a Package) that has an advantage that each module is processed in the best available technology. Each different chip can follow the appropriate technology node. For a SiP, purely digital circuits can be made ever smaller, while analog and RF (Radio Frequency) circuits with passive elements are larger. The multi-chip package configurations and techniques described may be used for other types of applications. While SiP packages are mentioned, this is not necessary to the invention.

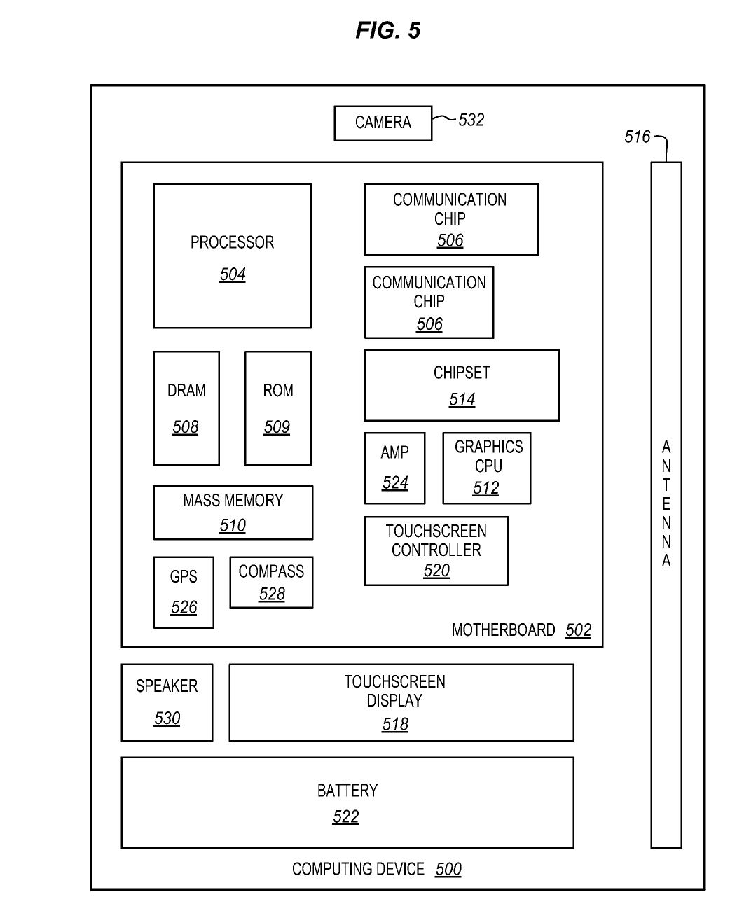

FIG. 5 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM) 508, non-volatile memory (e.g., ROM) 509, flash memory (not shown), a graphics processor 512, a digital signal processor (not shown), a crypto processor (not shown), a chipset 514, an antenna 516, a display 518 such as a touchscreen display, a touchscreen controller 520, a battery 522, an audio codec (not shown), a video codec (not shown), a power amplifier 524, a global positioning system (GPS) device 526, a compass 528, an accelerometer (not shown), a gyroscope (not shown), a speaker 530, a camera 532, and a mass storage device (such as hard disk drive) 510, compact disk (CD) (not shown), digital versatile disk (DVD) (not shown), and so forth). These components may be connected to the system board 502, mounted to the system board, or combined with any of the other components.

The communication chip 506 enables wireless and/or wired communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

In some implementations, any one or more of the components of FIG. 5, such as the integrated circuit die of the processor, memory devices, communication devices, or other components may be packaged together in a single package, as described herein. The term “processor” may refer to any device or portion of a device that processes electronic data from registers and/or memory to transform that electronic data into other electronic data that may be stored in registers and/or memory.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Embodiments may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

In the following description and claims, the terms “chip” and “die” are used interchangeably to refer to any type of microelectronic, micromechanical, analog, or hybrid small device that is suitable for packaging and use in a computing device.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to a method that includes forming a first and a second die, wherein the first and the second die each have a different height, placing the first and the second die on a substrate, grinding at least one of the first and the second die so that the first and the second die are about the same height, forming layers over both the first and the second die at the same time using a single process, and packaging the first and the second die and the formed layers.

In further embodiments forming layers includes forming a redistribution layer over the first and the second die. In further embodiments forming the redistribution layer includes forming at least one metal layer and at least one dielectric layer, the dielectric layer to isolate the first and the second die from the metal layer.

Further embodiments include forming connection pads to connect the metal layer to an external device. In further embodiments, packaging comprises forming additional layers over the first and the second die. Packaging comprises placing a cover over the first and the second die.

Further embodiments include removing the substrate before packaging the first and the second die. Further embodiments include applying a molding compound over the first and the second die after placing the first and the second die on the substrate, the method further comprising removing the substrate after applying the molding compound, and wherein forming layers comprises forming layers on a side of the dies from which the substrate was removed.

In further embodiments removing the substrate comprises grinding the substrate.

Some embodiments pertain to a multiple chip package including a first die having an original first height, a second die having an original second height, the first and the second dies being ground to about the same height after having been placed together on a substrate, a redistribution layer formed over both the first and the second die at the same time using a single process, and a package cover over the first and the second die.

In further embodiments the package cover comprises a filler layer between the first and the second die and over the redistribution layer to physically stabilize the first and the second die. The filler layer is a molding compound. The package cover comprises a metal shield attached to cover the first and second die and expose the redistribution layer. The first and the second dies are ground on a first side and the redistribution layer is formed on a second opposite side.

Further embodiments include a second redistribution layer formed over the first side. In Further embodiments the first redistribution layer electrically connects to external devices and the second redistribution layer electrically connects the first die to the second die.

Some embodiments pertain to a computing device including a user interface controller, a power supply, and a multiple chip package having a first processor having an original first height, a communications chip having an original second height, the processor and the communications chip being ground to about the same height after having been placed together on a substrate, a redistribution layer formed over both the processor and the communications chip at the same time using a single process, and a package cover over the processor and the second communications chip.

In further embodiments the substrate is removed by a solvent before the redistribution layer is formed in place of the substrate. The multiple chip package is an embedded wafer level ball grid array package.

1. A method comprising:
forming a first and a second die, wherein the first and the second die each have a different height;
placing the first and the second die on a substrate, so that a backside of each die is facing the substrate;
grinding at least one of the first and the second die on a side opposite the backside so that the first and the second die are about the same height;
removing the substrate;
forming layers over the backsides of both the first and the second die at the same time using a single process; and
packaging the first and the second die and the formed layers.

2. The method of claim 1, wherein forming layers comprises forming a redistribution layer over the first and the second die.

3. The method of claim 2, wherein forming the redistribution layer comprises forming at least one metal layer and at least one dielectric layer, the dielectric layer to isolate the first and the second die from the metal layer.

4. The method of claim 3, further comprising forming connection pads to connect the metal layer to an external device.

5. The method of claim 1, wherein packaging comprises forming additional layers over the first and the second die.

6. The method of claim 1, wherein packaging comprises placing a cover over the first and the second die.

7. The method of claim 1, further comprising forming vias on the substrate extending from the substrate and forming a redistribution layer coupled to the vias over the first and the second die on a side opposite the backside.

8. The method of claim 1, further comprising applying a molding compound over the first and the second die after placing the first and the second die on the substrate, the method further comprising removing the substrate after applying the molding compound, and wherein forming layers comprises forming layers on a side of the dies from which the substrate was removed.

9. The method of claim 8, wherein removing the substrate comprises grinding the substrate.

10. A multiple chip package comprising:
a first die having an original first height;
a second die having an original second height, the first height being different from the second height, the first and the second dies being subsequently ground to about the same height after having been placed together on a substrate so that a backside of each die is facing the substrate;
a redistribution layer formed over the backsides of both the first and the second die at the same time using a single process after removing the substrate; and
a package cover over the first and the second die.

11. The package of claim 10, wherein the package cover comprises a filler layer between the first and the second die and over the redistribution layer to physically stabilize the first and the second die.

12. The package of claim 11, wherein the filler layer is a molding compound.

13. The package of claim 10, wherein the package cover comprises a metal shield attached to cover the first and second die and expose the redistribution layer.

14. The package of claim 10, wherein the redistribution layer is formed of alternating metal layers and dielectric layers and connection pads to connect the metal layers to an external device.

15. The package of claim 14, wherein the first and the second dies are ground on a first side and the redistribution layer is formed on a second opposite side, the package further comprising a second redistribution layer formed over the first side.

16. The package of claim 15, wherein the first redistribution layer electrically connects to external devices and the second redistribution layer electrically connects the first die to the second die.

17. A computing device comprising:
a user interface controller;
a power supply; and
a multiple chip package having a first processor having an original first height, a communications chip having an original second height, the first height being different from the second height. the processor and the communications chip being subsequently ground to about the same height after having been placed together on a substrate so that a backside of each die is facing the substrate, a redistribution layer formed over the backsides of both the processor and the communications chip at the same time using a single process after removing the substrate, and a package cover over the processor and the second communications chip.

18. The computing device of claim 17, wherein the substrate is removed by a solvent before the redistribution layer is formed in place of the substrate.

19. (canceled)

20. The computing device of claim 17, wherein the package cover comprises a filler layer between the first and the second die and over the redistribution layer to physically stabilize the first and the second die.
